(19) United States
(12) Patent Application Publication
(10) Pub. No.: US 2024/0153795 A1
(43) Pub. Date: May 9, 2024

(54) MODULAR MICROWAVE SOURCE WITH INTEGRATED OPTICAL SENSORS

(71) Applicant: Applied Materials, Inc., Santa Clara, CA (US)

(72) Inventors: Adam Fischbach, Campbell, CA (US); Richard McKissick, San Jose, CA (US); Brian Hatcher, Santa Clara, CA (US); Christian Valencia, Alhambra, CA (US); Thai Cheng Chua, Cupertino, CA (US); Philip Allan Kraus, San Jose, CA (US)

(21) Appl. No.: 17/981,278

(22) Filed: Nov. 4, 2022

(51) Int. Cl. H01L 21/67; H01J 37/32; H01L 21/68

(52) U.S. Cl. CPC H01L 21/6719; H01J 37/32192; H01L 21/681

(57) ABSTRACT

Embodiments disclosed herein include a semiconductor processing tool. In an embodiment, the semiconductor processing tool comprises a chamber, and a lid configured to seal the chamber. In an embodiment, a modular microwave plasma applicator is provided through the lid, and an optical port is provided through the lid and adjacent to the modular microwave plasma source. In an embodiment, a pin is inserted in the optical port.

### BACKGROUND

### 1) Field

Embodiments relate to the field of semiconductor manufacturing and, in particular, to a plasma processing tool that includes modular microwave sources with integrated optical sensors for use in controlling plasma density.

### 2) Description of Related Art

In plasma processing environments, plasma properties are tightly controlled in order to provide uniform processing results on a substrate. Typically, plasma properties that may be controlled include plasma density, electron density, plasma temperature, and the like. Ideally, for uniform processing, the plasma properties are generally maintained as uniformly as possible across the surface of the substrate that is being processed. In the case of a traditional plasma processing tool, a single energy source (e.g., an RF source, a microwave source, or the like) is used to ignite and maintain the plasma. As such, there is a limited number of knobs that can be tuned in order to modulate plasma properties across the surface of the substrate. In more advanced processing environments, multiple energy sources (and applicators) may be provided. The addition of more applicators allows for additional degrees of freedom in order to modulate the plasma properties.

Typically, plasma properties are measured through the use of optical emission spectroscopy (OES). The OES system includes a port along the sidewall of the plasma chamber. Optical signals from the plasma propagate out of the port to a controller. However, since the OES port is along the sidewall, only an average of the plasma properties can be obtained. That is, there is no ability to spatially resolve different regions of the plasma chamber (e.g., center, edge, etc.). Accordingly, the OES data does not enable advanced spatial tuning (e.g., to provide improved uniformity or other desired plasma profiles).

### SUMMARY

Embodiments disclosed herein include a semiconductor processing tool. In an embodiment, the semiconductor processing tool comprises a chamber, and a lid configured to seal the chamber. In an embodiment, a modular microwave plasma applicator is provided through the lid, and an optical port is provided through the lid and adjacent to the modular microwave plasma source. In an embodiment, a pin is inserted in the optical port.

Embodiments disclosed herein may also include a semiconductor processing tool that comprises a chamber with a lid, and a plurality of microwave applicators through the lid. In an embodiment, a plurality of microwave power sources are provided where each of the plurality of microwave power sources is coupled to a different one of the plurality of microwave applicators. In an embodiment, a plurality of optical ports are provided through the lid, and a controller is provided, where the plurality of optical ports and the plurality of microwave power sources are communicatively coupled to the controller.

Embodiments disclosed herein may also include a method of controlling a plasma process. In an embodiment, the method comprises providing a plurality of microwave power sources for supporting modular plasmas in a chamber, and obtaining optical signals from the modular plasmas with a plurality of optical sensors. In an embodiment, the method comprises delivering optical signals to a controller, and determining, with the controller, microwave power and frequency settings for the plurality of microwave power sources in order to produce a desired plasma density uniformity in the chamber.

### BRIEF DESCRIPTION OF THE DRAWINGS

FIG. 1 is a cross-sectional illustration of a plasma chamber with an optical emission spectroscopy (OES) port on the sidewall of the chamber.

FIG. 2 is a cross-sectional illustration of a modular microwave plasma chamber with an OES port through the lid of the chamber, in accordance with an embodiment.

FIG. 3 is a zoomed in cross-sectional illustration that more clearly depicts the structure of the modular microwave applicator and the OES port, in accordance with an embodiment.

FIG. 4A is a plan view illustration of the lid that shows the layout of modular microwave applicators and OES ports around a perimeter of the lid, in accordance with an embodiment.

FIG. 4B is a plan view illustration of the lid that shows the layout of modular microwave applicators and OES ports around a perimeter of the lid, in accordance with an embodiment.

FIG. 4C is a plan view illustration of the lid that shows the layout of modular microwave applicators and OES ports that are distributed across an entire surface of the lid, in accordance with an embodiment.

FIG. 5 is a cross-sectional illustration of a plasma chamber that includes modular microwave applicators that are controlled by a machine learning (ML) or artificial intelligence (AI) controller that uses feedback from one or more OES ports and from the microwave power sources, in accordance with an embodiment.

FIG. 6 is a process flow diagram of a process for controlling a plasma density within a modular microwave plasma chamber with an ML or AI controller, in accordance with an embodiment.

FIG. 7 illustrates a block diagram of an exemplary computer system that may be used in conjunction with a processing tool, in accordance with an embodiment.

### DETAILED DESCRIPTION

Systems described herein include a plasma processing tool that includes modular microwave sources with integrated optical sensors for use in controlling plasma density. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, optical emission spectroscopy (OES) can be used in order to determine one or more plasma parameters in a plasma processing tool. Unfortunately, existing solutions do not allow for discernment of plasma properties spatially within the chamber. This is because the OES port is generally provided on the sidewall of the chamber. An average of the plasma property of interest is suitable for chambers that include a single power source and/or applicator since it is much more difficult to make variations in the plasma across the surface of the substrate.

However, in more advanced semiconductor processing tools, such as modular microwave plasma tools, the ability to tune the plasma across the surface of the substrate is much more attainable. In some instances, the plurality of microwave applicators may be tuned in order to provide improved plasma uniformity, or the microwave applicators may be tuned to provide a non-uniform plasma profile in order to account for incoming substrate non-uniformity, warpage, or the like. Accordingly, it is desirable to provide feedback control that is informed by spatial mapping of the plasma.

In some embodiments disclosed herein, the plasma is monitored through OES ports that are provided through a lid of the chamber instead of through the side. As such, a plurality of OES ports can be used in order to determine plasma properties across the surface of the substrate. This feedback can be used by a controller (e.g., a machine learning (ML) controller or an artificial intelligence (AI) controller) in order to modify the settings of individual microwave applicators. For example, power, frequency, and the like that are provided to the microwave applicators can be modified in order to provide a desired plasma profile.

Providing the OES ports through the lid also allows for the substrate to be brought closer to the faceplate of the lid. This is because there is no need for a horizontal port through the sidewall of the chamber above the height of the substrate. In some embodiments, the OES ports are provided entirely outside of the perimeter of the substrate being processed in the chamber. This may be beneficial in that the OES ports will not negatively affect the plasma seen by the substrate. However, in other embodiments, one or more OES ports may be provided within the perimeter of the substrate being processed in the chamber.

In an embodiment, the OES ports may be filled with a transparent (to the electromagnetic radiation) pin. For example, the pin may include sapphire or quartz in some embodiments. The pins fill up the space of the OES port and prevent igniting a plasma in the cavity (i.e., through a hollow cathode effect). In some instances the pins may also be a two part pin. A first part of the pin may be provided in the faceplate, and a second part of the pin may be provided in the cover. The two parts accommodate any coefficient of thermal expansion (CTE) mismatch between the layers without fracturing the pin.

In some embodiments, the controller of the plasma processing chamber may receive feedback from one or more of the OES ports and/or one or more of the microwave power sources. The feedback may be used in order to adjust and tune the plasma within the chamber. However, embodiments are not limited to simple controller architectures (e.g., closed loop control). As noted above, the controller may be an ML controller or an AI controller. In such embodiments, the controller may learn from the OES feedback. For example, the controller may learn how changes to one or more parameter of the microwave power source will affect the plasma. This learning data can be leveraged in order to more precisely and timely tune the plasma to a desired state. ML and AI control may also be used in order to determine how multiple microwave applicators affect each other such as through a multiple input multiple output (MIMO) control system. Through learning, the controller is able to build a more accurate digital twin of the processing chamber that provides modelling that can augment existing modelling that relies solely on physical and chemical equations that describe the process.

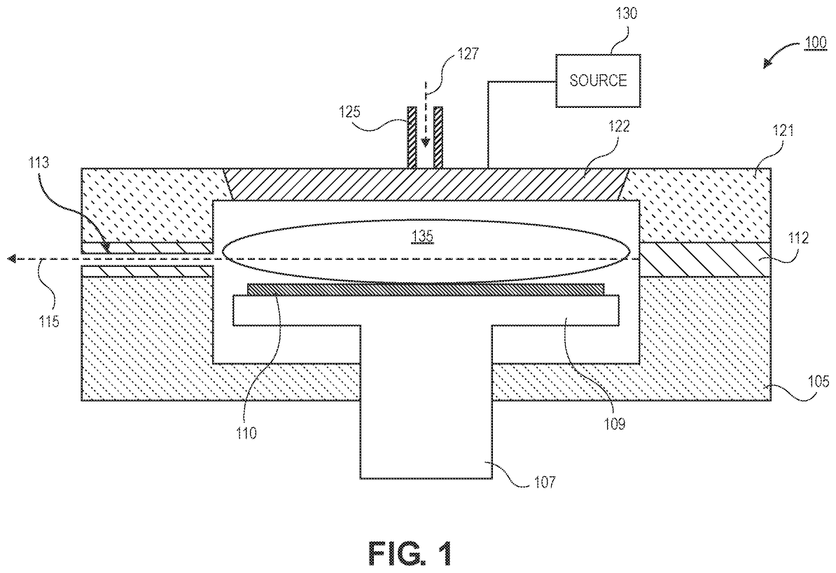

Referring now to FIG. 1, a cross-sectional illustration of a semiconductor processing tool 100 is shown, in order to provide context for embodiments described in greater detail below. As shown, the semiconductor processing tool 100 may include a chamber body 105. The chamber body 105 may be closed by a lid 121. In an embodiment, a pedestal 107 supports a chuck 109. The pedestal 107 may be vertically displaceable within the chamber body 105 in order to position a substrate 110 within the chamber body 105.

The substrate 110 may be a typical substrate processed with plasma processing operations. For example, the substrate 110 may include a semiconductor substrate, such as a wafer or the like. Though, other form factors may also be used in some instances. In the illustration of FIG. 1, the diameter of the substrate 110 is smaller than the diameter of the chuck 109. Though in some instances, the substrate 110 may extend past an edge of the chuck 109. The chuck 109 may be an electrostatic chuck (ESC) or any other suitable chucking mechanism. The chuck 109 may include heating and/or cooling solutions in order to control a temperature of the substrate 110 during processing.

In the illustration of FIG. 1, an adapter 112 separates the chamber body 105 from the lid 121. The adapter 112 may include a port 113. Electromagnetic radiation 115 from a plasma 135 within the chamber body 105 may be propagated out of the port 113. Since the port 113 is on a side of the tool 100, the electromagnetic radiation 115 is from an entire width of the plasma 135. That is, it is difficult (if not impossible) to obtain spatial understanding of the plasma 135. All that is received is an average through the plasma 135. Additionally, when the port is above the substrate 110 (in order to monitor the processing region of the tool 100), the distance between the showerhead 122 and the substrate 110 is increased.

The showerhead 122 may include channels (not shown) for flowing one or more gasses 127 into the chamber body 105. For example, one or more inlets 125 may be coupled to the showerhead 122. Additionally, the showerhead 122 may function as the electrode for coupling energy into the chamber body 105. For example, the showerhead 122 may be coupled to a source 130, such as an RF source, a microwave source, or the like. While not shown, a second source may be coupled to the chuck 109 in some instances as well.

In the illustration of FIG. 1, the tool 100 can be described as having a single source or a single applicator. That is, there is limited control of the plasma over the surface of the substrate 110. However, as tools continue to advance, one promising solution is to use a modular source. In such an embodiment, the power coupled into the chamber is provided by a plurality of applicators. Each applicator can be independently controlled in order to provide a desired plasma profile across the surface of the substrate. In a particular embodiment, a plurality of microwave power sources can be used with a plurality of microwave applicators. In such an embodiment, it may be desirable to provide more spatially resolved feedback in order to control the plasma profile across the surface of the substrate.

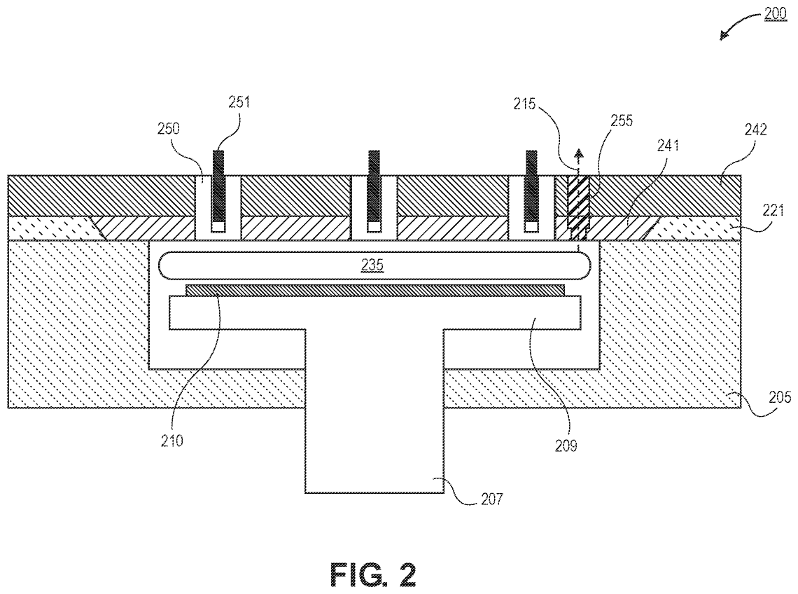

Accordingly, embodiments with OES ports through a top surface or lid of the chamber are described. Referring now to FIG. 2, a cross-sectional illustration of one such semiconductor processing tool 200 is shown, in accordance with an embodiment. In an embodiment, the semiconductor processing tool 200 includes a chamber body 205. The chamber body 205 may be sealed by a lid 221 in order to define an interior volume in which a plasma 235 can be formed. In an embodiment, the semiconductor processing tool 200 may include a pedestal 207 and a chuck 209. The pedestal 207 may be vertically displaceable in order to modify a position of the substrate 210 within the chamber body 205. In an embodiment, the chuck 209 may be an ESC or the like. The chuck 209 may include heating and/or cooling solutions in order to control a temperature of the substrate 210 during processing.

In an embodiment, the substrate 210 may be a semiconductor substrate. For example, the substrate 210 may be a silicon wafer with a standard form factor (e.g., 150 mm, 200 mm, 300 mm, 450 mm, etc.). However, in other embodiments the substrate 210 may have other form factors, such as a reticle form factor, a panel form factor, or the like. In an embodiment, a diameter of the substrate 210 may be smaller than a diameter of the chuck 209, as shown in FIG. 2. However, in some embodiments, the substrate 210 may overhang an edge of the chuck 209.

In an embodiment, a showerhead or the like may be disposed through the lid 221. In the embodiment shown in FIG. 2, the showerhead comprises a faceplate 241 and a cover 242. The faceplate 241 may be directly exposed to the interior of the chamber body 205, and the cover 242 may be provided over the faceplate 241. The faceplate 241 and the cover 242 may be different materials. For example, the faceplate 241 may be a conductor and the cover 242 may be an electrically insulating material.

In an embodiment, the showerhead may include fluidic paths (not shown) through one or both of the faceplate 241 and the cover 242. The fluidic paths may be suitable for flowing one or more gasses into the chamber body 205. The gasses flown into the chamber body 205 may be ignited into a plasma 235. The plasma 235 may be provided above the substrate 210. In an embodiment, the width of the plasma 235 may be wider than a diameter of the substrate 210.

In an embodiment, a plurality of modular applicators 250 may be provided through the showerhead. The modular applicators 250 may comprise a dielectric body with a hole into, but not through, a top surface of the dielectric body. Antennas 251 may be provided in the holes. The antennas 251 are electrically conductive features that are coupled to power sources (not shown). In a particular embodiment, the power sources are modular microwave power sources. As such, each of the applicators 250 may be coupled to a microwave source in order to transfer microwave power into the chamber body 205 in order to strike and maintain the plasma 235. In an embodiment, the bottom surface of the applicators 250 (that is, the bottom dielectric surface) is exposed at the bottom of the showerhead within the chamber body 205.

In an embodiment, the semiconductor processing tool 200 may further comprise one or more OES ports 255. The OES ports 255 may include a port through the showerhead (i.e., faceplate 241 and cover 242). The OES port 255 may be filled with a pin, such as a pin transparent to electromagnetic radiation emitted by the plasma 235. For example, the pin may comprise sapphire, quartz, or the like. As shown, electromagnetic radiation 215 emitted by the plasma 235 passes through the OES port 255.

In an embodiment, the OES port 255 is provided outside a perimeter of the substrate 210. As such, the surface of the OES port 255 may not directly interfere with the plasma over the substrate 210. However, as will be described in greater detail below, one or more OES ports 255 may also be provided within a perimeter of the substrate 210. Additionally, since the OES port 255 is formed above the plasma 235, the plasma properties at a given area can be determined, as opposed to receiving an average of the plasma properties within the chamber body 205. Furthermore, since the OES port 255 is above the substrate 210, the substrate 210 can be brought closer to the faceplate 241.

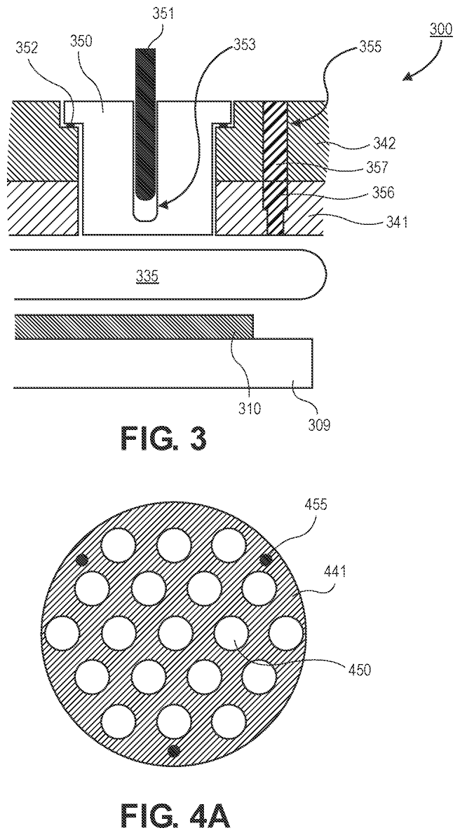

Referring now to FIG. 3, a zoomed in cross-sectional illustration depicting a portion of a semiconductor processing tool 300 is shown, in accordance with an additional embodiment. As shown, the semiconductor processing tool 300 may comprise a chuck 309 and a substrate 310 over the chuck 309. The chuck 309 and the substrate 310 may be substantially similar to the chuck 209 and substrate 210 described in greater detail above. In an embodiment, a showerhead comprising a faceplate 341 and a cover 342 may be provided over the chuck 309 and the substrate 310. A plasma 335 may be formed between the faceplate 341 and the substrate 310.

In an embodiment, a modular applicator 350 may be provided through the cover 342 and the faceplate 341. As shown, the modular applicator 350 may have a stepped cylindrical design. A first cylinder with a first diameter may be provided below a second cylinder with a second (larger) diameter. The larger second diameter may be sufficient to provide a ledge that a seal ring 352 (e.g., an O-ring) can rest upon. As such, the modular applicator 350 may provide a seal between the external environment and an internal processing area where the plasma 335 is formed.

In an embodiment, the modular applicator 350 may comprise a hole 353. The hole 353 may be provided in an axial center of the modular applicator 350. The hole 353 may have a rounded bottom surface. Additionally, an antenna 351 may be inserted into the hole 353. The antenna 351 may have a gap between a bottom surface and a bottom surface of the hole 353. The gap may allow for expansion of the antenna 351 during use. The antenna 351 may be coupled to a microwave power source (not shown). While a single modular applicator 350 is shown in FIG. 3, it is to be appreciated that any number of modular applicators 350 may be included in the semiconductor processing tool 300.

In an embodiment, an OES port 355 may be provided through the faceplate 341 and the cover 342. The OES port 355 may be filled with a pin 356/357. The pin 356/357 may be separated into two distinct components (i.e., a bottom pin 356 and a top pin 357. The use of two discrete pins 356 and 357 allows for thermal expansion mismatch between the faceplate 341 and the cover 342 (e.g., due to different CTEs between the materials). If a single pin was used, thermal expansion mismatch may result in the single pin fracturing. Though, in some embodiments, a single pin to fill the OES port 355 may be sufficient.

In an embodiment, the pin 356/357 may be formed of a material that is substantially transparent to the electromagnetic radiation emitted by the plasma 335. For example, the pin 356/357 may comprise sapphire, quartz, or the like. In one embodiment, the bottom pin 356 may have dual diameters. A first diameter may be at the lower end of the bottom pin 356, and a second (larger) diameter may be at the upper end of the bottom pin 356. The diameter of the top pin 357 may substantially match the second diameter of the upper end of the bottom pin 356. In an embodiment, the OES port 355 may be substantially filled by the pin 356/357. As such, there is no gap within the showerhead where a plasma can form (i.e., through a hollow cathode effect).

The OES port 355 may be coupled to an optical waveguide (not shown) in order to transfer the optical signal from the chamber to a controller (not shown). The controller may convert the optical signal into measurements of one or more plasma properties (e.g., plasma density, electron density, plasma temperature, etc.). A coupler (not shown) may couple the OES port 355 to the optical waveguide.

In the illustrated embodiment, the OES port 355 is provided outside of a diameter of the substrate 310. However, in other embodiments, the OES port 355 may be provided within a diameter of the substrate 310. While a single OES port 355 is shown in FIG. 3, it is to be appreciated that any number of OES ports 355 may be provided in the semiconductor processing tool 300.

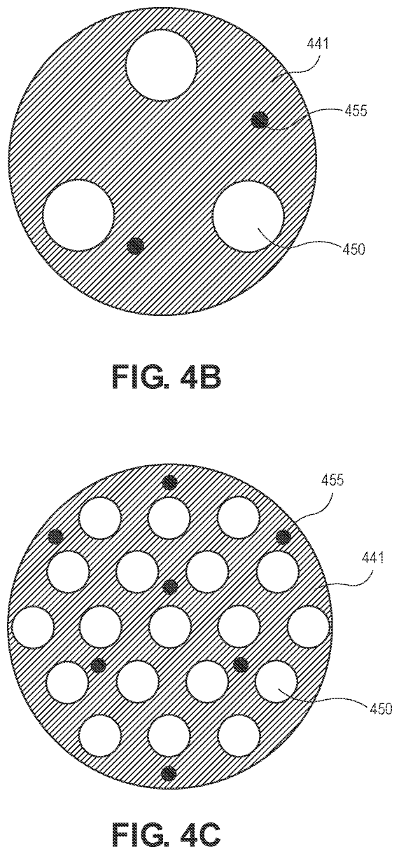

Referring now to FIGS. 4A-4C, a series of plan view illustrations depicting a layout of the modular microwave applicators 450 and OES ports 455 in a faceplate 441 is shown in accordance with an embodiment. It is to be appreciated that the examples shown in FIGS. 4A-4C are merely illustrative of some embodiments. That is to say, embodiments are not limited to those shown in FIGS. 4A-4C.

Referring now to FIG. 4A, a plan view illustration of a faceplate 441 is shown, in accordance with an embodiment. The faceplate 441 may be part of a showerhead that is integrated into a lid of a semiconductor processing tool, such as those described in greater detail above. In an embodiment, a plurality of modular microwave applicators 450 may be distributed about a surface of the faceplate 441. For example 19 modular microwave applicators 450 are shown in FIG. 4A. Though, it is to be appreciated that a fewer number or a greater number of modular microwave applicators 450 may be included in the faceplate 441.

In an embodiment, a set of three OES ports 455 are distributed on the faceplate 441. The OES ports 455 may be provided outside of a diameter of a substrate (not shown) processed in the semiconductor processing tool. For example, the OES ports 455 are shown as being distributed proximate to an outer perimeter of the faceplate 441. Additionally, while three OES ports 455 are shown, it is to be appreciated that any number of OES ports 455 may be included in the faceplate 441.

In an embodiment, the distribution of the OES ports 455 allow for measuring the plasma properties at various locations within the chamber. This allows for a plasma uniformity measurement to be determined. Instead of using a single port that averages the plasma property across the entire surface of the substrate, embodiments disclosed herein allow for plasma properties to be determined at a plurality of different locations.

Referring now to FIG. 4B, a plan view illustration of a faceplate 441 is shown, in accordance with yet another embodiment. As compared to the embodiment in FIG. 4A, the number of modular microwave applicators 450 is reduced. Particularly, a set of three modular microwave applicators 450 are shown. In an embodiment, the microwave applicators 450 may be larger than the microwave applicators 450 in FIG. 4A. In other embodiments, the microwave applicators 450 may be provided on a smaller faceplate 441. For example, the faceplate 441 and microwave applicator 450 configuration shown in FIG. 4B may be used in a remote plasma system. That is, the plasma may be generated in an antechamber outside of the main processing chamber, and the plasma may be flown into the main processing chamber.

As shown, a plurality of OES ports 455 may be distributed across the faceplate 441. The OES ports 455 may include two OES ports 455. In other embodiments, the number of OES ports 455 may be equal to the number of modular microwave applicators 450. In an embodiment, the OES ports 455 are provided proximate to a perimeter of the faceplate 441. However, one or more of the OES ports 455 may be towards a middle of the faceplate 441 in some embodiments.

Referring now to FIG. 4C, a plan view illustration of a faceplate 441 is shown, in accordance with an additional embodiment. In the embodiment shown in FIG. 4C, the distribution and number of modular microwave applicators 450 is substantially similar to the layout shown in FIG. 4A. However, as shown in FIG. 4C, the OES ports 455 may be distributed across an entire surface of the faceplate 441 instead of being limited to the outer perimeter of the faceplate 441. For example, a total of seven OES ports 455 are shown in FIG. 4C. In an embodiment, one or more of the OES ports 455 may be within an outer perimeter of a substrate (not shown) that is being processed in a chamber below the faceplate 441.

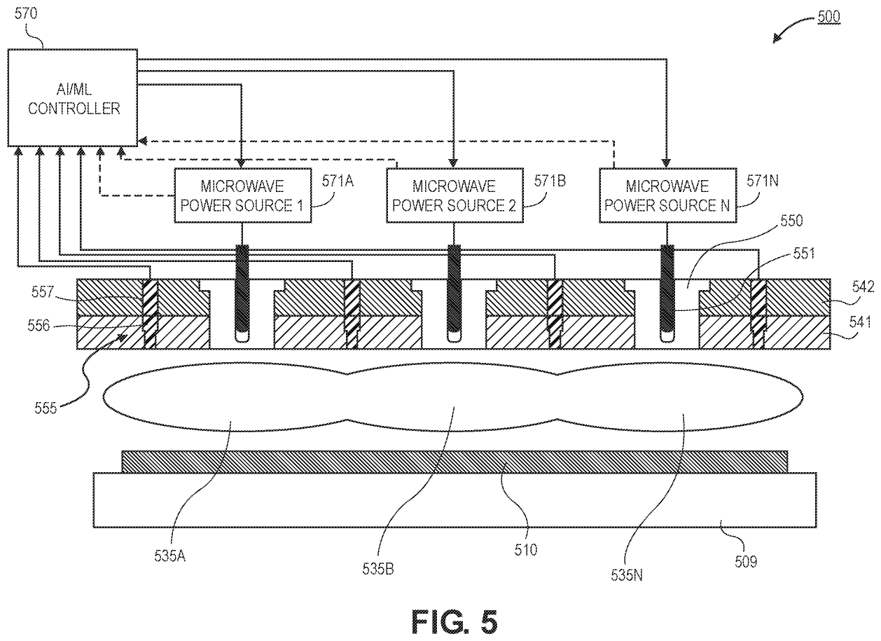

Referring now to FIG. 5, a cross-sectional illustration of a semiconductor processing tool 500 is shown, in accordance with an embodiment. In an embodiment, the semiconductor processing tool 500 may include a chuck 509 with a substrate 510 provided on the chuck 509. A showerhead comprising a faceplate 541 and a cover 542 may be provided over the substrate 510. In an embodiment, a plurality of microwave applicators 550 are provided through the showerhead. Antennas 551 may be provided in the axial center of each of the microwave applicators 550. The microwave applicators 550 may couple energy from microwave power sources 571 into the chamber to form plasma 535. As shown, the plasma 535 may be formed of a plurality of plasma regions 535A-535N. That is, each microwave applicator 550 may form a plasma region directly below the given microwave applicator 550, and the adjacent plasma regions may merge together. While three plasma regions 535A-535N are shown, it is to be appreciated that any number of plasma regions 535 may be formed, depending on the number of modular microwave applicators 550. As shown, each of the microwave applicators 550 may be coupled to different ones of the microwave power sources 571A-571N. As such, the plasma regions 535 may be independently controllable.

In an embodiment, the semiconductor processing tool 500 may include a plurality of OES ports 555. Each OES port 555 may be filled by a pin that includes a lower pin 556 and an upper pin 557. Each of the OES ports 555 may be coupled to a controller 570. The OES ports 555 provide feedback data to the controller 570 in order to aid in the control of the plasma regions 535A-535N. For example, optical signals from the OES ports 555 may be converted into one or more plasma properties (e.g., plasma density, electron density, plasma temperature, etc.) by the controller 570. The controller 570 may also receive feedback from the microwave power sources 571A-571N. For example, forward power, reflected power, frequency, and the like may be provided back to the controller as additional feedback information.

In an embodiment, the controller 570 takes the feedback information from the OES ports 555 and the microwave power sources 571 and uses the feedback information in order to change one or more parameters of the plasma. This is done by feeding one or more control signals back to the microwave power sources 571. For example, the controller 570 may send signals to the power sources 571 that result in a change to forward power, frequency, match settings, or the like.

In one embodiment, the controller 570 may be a standard closed loop controller. In other embodiments, the controller 570 may be an ML controller and/or an AI controlled. In the case of ML and AI, the controller 570 may further learn from the feedback information in order to more precisely and timely control the plasma regions 535. For example, feedback data can be used in order to learn how the semiconductor processing tool 500 reacts to changes in one or more parameters. The ML and/or AI controller 570 may allow for more accurate understanding of the conditions within the semiconductor processing tool 500. For example, the ML and/or AI controller can aid in the formation of a digital twin of the semiconductor processing tool that extends beyond standard physics and chemistry based equations to model the semiconductor processing tool 500. Further, the ML and/or AI controller 570 may aid the performance of MIMO control of the system. As such, improved plasma uniformity can be obtained using embodiments disclosed herein.

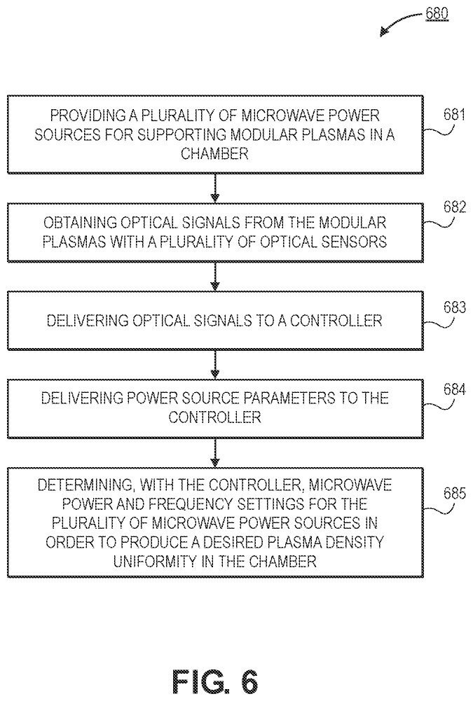

Referring now to FIG. 6, a process flow diagram of a process 680 for controlling a plasma processing tool is shown, in accordance with an embodiment. The process 680 may be executed in any of the plasma processing tools described in greater detail herein.

In an embodiment, the process 680 begins with operation 681 which comprises providing a plurality of microwave power sources for supporting modular plasmas in a chamber. For example, the microwave power sources may be coupled to plasma applicators that pass through a showerhead of a lid of a plasma chamber. The plasma applicators couple the microwave power into a processing gas in the plasma chamber in order to strike and maintain a plasma. As used herein, modular plasmas may refer to a plasma that is formed by the use of multiple modular microwave applicators. That is, each region of a modular plasma may be controlled by the overlying microwave applicator and the connected microwave power source.

In an embodiment, the process 680 may continue with operation 682, which comprises obtaining optical signals from the modular plasma with a plurality of optical sensors. For example, OES ports may be provided through a lid of the plasma chamber. The OES ports may be provided around a perimeter of the lid. In other embodiments, the OES ports may be provided in a middle region of the lid. The OES ports may comprise a pin structure of optically transparent material (e.g., sapphire or quartz).

In an embodiment, the process 680 may continue with operation 683, which comprises delivering optical signals to a controller. The optical signals may be delivered to a controller by optically coupling the OES ports to the controller (e.g., with fiber optic cables or the like).

In an embodiment, the process 680 may continue with operation 684, which comprises delivering power source parameters to the controller. In an embodiment, the power source parameters may include forward power, reflected power, frequency, and the like. The power source parameters and the optical signals may be used as feedback by the controller.

In an embodiment, the process 680 may continue with operation 685, which comprises determining, with the controller, microwave power and frequency settings for the plurality of microwave power sources in order to produce a desired plasma uniformity in the chamber. In some embodiments, the plasma uniformity may refer to a plasma density, an electron density, a plasma temperature, or the like. In some instances, the controller may be a simple closed loop controller. In other embodiments, the controller may utilize ML and/or AI modules in order to improve process control within the chamber.

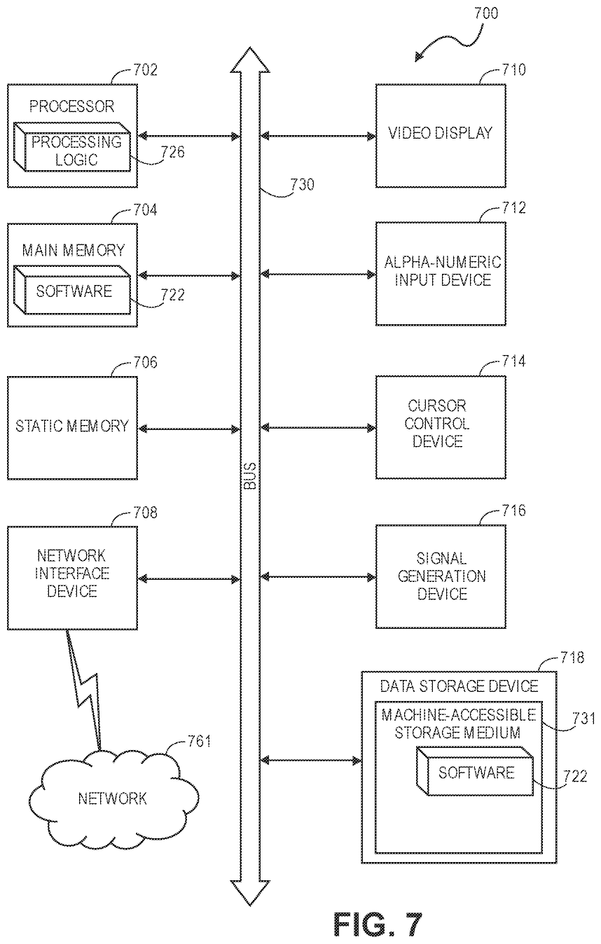

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 732 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 720 via the system network interface device 708. In an embodiment, the network interface device 708 may operate using RF coupling, optical coupling, acoustic coupling, or inductive coupling.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A semiconductor processing tool, comprising:
a chamber;
a lid configured to seal the chamber;
a modular microwave plasma applicator through the lid;
an optical port through the lid and adjacent to the modular microwave plasma source; and
a pin inserted in the optical port.

2. The semiconductor processing tool of claim 1, wherein the pin comprises sapphire or quartz.

3. The semiconductor processing tool of claim 1, wherein the lid comprises a faceplate and a cover, and wherein the pin passes through both the faceplate and the cover.

4. The semiconductor processing tool of claim 3, wherein the pin comprises a first portion in the faceplate and a second portion in the cover, wherein the first portion is a distinct piece from the second portion.

5. The semiconductor processing tool of claim 1, wherein the pin includes a first width at a first surface that is exposed in the chamber, and a second width at a second surface that is exposed outside of the chamber.

6. The semiconductor processing tool of claim 1, wherein the modular microwave plasma applicator comprises:
a dielectric body with a hole into, but not through, the dielectric body; and
an antenna inserted into the hole.

7. The semiconductor processing tool of claim 6, wherein a bottom surface of the dielectric body is exposed to an interior of the chamber.

8. The semiconductor processing tool of claim 1, further comprising:
a plurality of modular microwave plasma applicators, a plurality of optical ports, and a plurality of pins.

9. The semiconductor processing tool of claim 8, wherein the plurality of optical ports and the plurality of pins are located around a perimeter of the semiconductor processing tool.

10. The semiconductor processing tool of claim 9, further comprising a substrate in the chamber, and wherein the plurality of optical ports and the plurality of pins are located outside of a perimeter of the substrate.

11. A semiconductor processing tool, comprising:
a chamber with a lid;
a plurality of microwave applicators through the lid;
a plurality of microwave power sources, wherein each of the plurality of microwave power sources is coupled to a different one of the plurality of microwave applicators;
a plurality of optical ports through the lid; and
a controller, wherein the plurality of optical ports and the plurality of microwave power sources are communicatively coupled to the controller.

12. The semiconductor processing tool of claim 11, wherein the controller converts optical signals from the plurality of optical ports into plasma density measurements.

13. The semiconductor processing tool of claim 11, wherein the controller is configured to provide microwave parameters to the plurality of microwave power sources in order to control a plasma uniformity within the chamber.

14. The semiconductor processing tool of claim 13, wherein the microwave parameters include a microwave power and a microwave frequency.

15. The semiconductor processing tool of claim 13, wherein the individual ones of the plurality of microwave power sources receive different microwave parameters.

16. The semiconductor processing tool of claim 11, wherein the controller receives feedback from the plurality of microwave power sources.

17. The semiconductor processing tool of claim 16, wherein the feedback comprises a forward power, a reflected power, and a microwave frequency.

18. The semiconductor processing tool of claim 11, wherein the controller is a machine learning (ML) controller or an artificial intelligence (AI) controller.

19. A method of controlling a plasma process, comprising:
providing a plurality of microwave power sources for supporting modular plasmas in a chamber;
obtaining optical signals from the modular plasmas with a plurality of optical sensors;
delivering optical signals to a controller; and
determining, with the controller, microwave power and frequency settings for the plurality of microwave power sources in order to produce a desired plasma density uniformity in the chamber.

20. The method of claim 19, wherein the controller is a machine learning (ML) controller or an artificial intelligence (AI) controller.
